(19) United States
(12) Patent Application Publication
(10) Pub. No.: US 2025/0149315 A1
(43) Pub. Date: May 8, 2025

(54) ADJUSTMENT METHOD AND PLASMA PROCESSING APPARATUS

(71) Applicant: Tokyo Electron Limited, Tokyo (JP)

(72) Inventors: Naoki MATSUMOTO, Miyagi (JP); Toshihisa OZU, Miyagi (JP); Satoru NAKAMURA, Miyagi (JP); Yusuke SHIMIZU, Gyeonggi-do (KR)

(73) Assignee: Tokyo Electron Limited, Tokyo (JP)

(21) Appl. No.: 19/001,626

(22) Filed: Dec. 26, 2024

Related U.S. Application Data
(63) Continuation of application No. PCT/JP2023/023761, filed on Jun. 27, 2023.

(30) Foreign Application Priority Data
Jun. 30, 2022 (JP) 2022-106360

(51) Int. Cl. H01J 37/32

(52) U.S. Cl. CPC H01J 37/32926; H01J 37/32724; H01J 2237/334

(57) ABSTRACT

An adjustment method includes: acquiring reference distribution data that is data on a distribution of an ion flux that occurs between plasma generated in a first chamber and a substrate placed at a first substrate support disposed in the first chamber in a first plasma processing apparatus including the first chamber and the first substrate support; acquiring distribution data that is data on a distribution of an ion flux that occurs between plasma generated in a second chamber and a substrate placed at a second substrate support disposed in the second chamber in a second plasma processing apparatus including the second chamber and the second substrate support; and adjusting an element capable of adjusting the ion flux in the second plasma processing apparatus based on the distribution data acquired in the second plasma processing apparatus and the reference distribution data acquired in the first plasma processing apparatus.

### CROSS-REFERENCE TO RELATED APPLICATIONS

This application is a bypass continuation application of international application No. PCT/JP2023/023761 having an international filing date of Jun. 27, 2023 and designating the United States, the international application being based upon and claiming the benefit of priority from Japanese Patent Application No. 2022-106360, filed on Jun. 30, 2022, the entire contents of each are incorporated herein by reference.

### TECHNICAL FIELD

An exemplary embodiment of the present disclosure relates to an adjustment method and a plasma processing apparatus.

### BACKGROUND

As a technology for measuring plasma at the surface of a wafer, there is an on-wafer monitoring system described in JP-A-2003-282546.

### CITATION LIST

### Patent Documents

Patent Document 1: JP-A-2003-282546

### SUMMARY

The present disclosure provides a technology for correcting inter-apparatus differences that occur among multiple plasma processing apparatuses.

An adjustment method according to one exemplary embodiment of the present disclosure includes: (a) acquiring reference distribution data that is data on a distribution of an ion flux that occurs between plasma generated in a first chamber and a substrate placed at a first substrate support disposed in the first chamber in a first plasma processing apparatus including the first chamber and the first substrate support; (b) acquiring distribution data that is data on a distribution of an ion flux that occurs between plasma generated in a second chamber and a substrate placed at a second substrate support disposed in the second chamber in a second plasma processing apparatus including the second chamber and the second substrate support; and (c) adjusting an element capable of adjusting the ion flux in the second plasma processing apparatus based on the distribution data acquired in the second plasma processing apparatus and the reference distribution data acquired in the first plasma processing apparatus.

One exemplary embodiment of the present disclosure can provide a technology for) correcting inter-apparatus differences that occur among multiple plasma processing apparatuses.

### BRIEF DESCRIPTION OF DRAWINGS

FIG. 1 illustrates a plasma processing system according to one or more embodiments of the present application.

FIG. 2 illustrates an example of the configuration of a capacitively coupled plasma processing apparatus according to one or more embodiments of the present application.

FIG. 3 shows an example of the upper surface of a substrate support 11 according to one or more embodiments of the present application.

FIG. 4 shows an example of a cross section of the substrate support 11 according to one or more embodiments of the present application.

FIG. 5 is a block diagram showing an example of the configuration of a control substrate 80 according to one or more embodiments of the present application.

FIG. 6 is a flowchart showing a method according to one or more embodiments of the present application.

FIG. 7 is a flowchart showing an example of step ST1.

FIG. 8 shows an example of reference distribution data.

FIG. 9 is a flowchart showing an example of step ST2.

FIG. 10 shows an example of distribution data.

FIG. 11 is a flowchart showing an example of step ST3.

FIG. 12 is a flowchart showing a method according to one or more embodiments of the present application.

FIG. 13 is a flowchart showing an example of step ST0.

FIG. 14 illustrates a plasma processing apparatus according to one or more embodiments of the present application.

### DETAILED DESCRIPTION

According to one or more embodiments of the present disclosure will be described below.

According to one or more embodiments, there is provided an adjustment method including the steps of: (a) acquiring reference distribution data that is data on a distribution of an ion flux that occurs between plasma generated in a first chamber and a substrate placed at a first substrate support disposed in the first chamber in a first plasma processing apparatus including the first chamber and the first substrate support; (b) acquiring distribution data that is data on a distribution of an ion flux that occurs between plasma generated in a second chamber and a substrate placed at a second substrate support disposed in the second chamber in a second plasma processing apparatus including the second chamber and the second substrate support; and (c) adjusting an element capable of adjusting the ion flux in the second plasma processing apparatus based on the distribution data acquired in the second plasma processing apparatus and the reference distribution data acquired in the first plasma processing apparatus.

According to one or more embodiments, the step (a) includes the steps of (a-1) placing the substrate at the first substrate support, (a-2) generating the plasma in the first chamber to perform plasma processing on the substrate, (a-3) supplying power to each of multiple first heaters disposed in the first substrate support, (a-4) acquiring the power supplied to each of the multiple first heaters in the state in which the plasma is generated in the first chamber, and (a-5) calculating the reference distribution data based on the power acquired for each of the multiple first heaters in the step (a-4).

According to one or more embodiments, the step (b) includes the steps of (b-1) placing the substrate at the second substrate support, (b-2) generating the plasma in the second chamber to perform plasma processing on the substrate, (b-3) supplying power to each of multiple second heaters disposed in the second substrate support, (b-4) acquiring the power supplied to each of the multiple second heaters in the state in which the plasma is generated in the second chamber, and (b-5) calculating the distribution data based on the power acquired for each of the multiple second heaters in the step (b-4).

According to one or more embodiments, the element in the step (c) includes at least one of a parameter relating to plasma processing in the second plasma processing apparatus and a parameter relating to a structure of the second plasma processing apparatus.

According to one or more embodiments, the method further includes the step of (d) creating a table that associates an amount of change in the distribution of the ion flux with an amount of change in the element capable of adjusting the distribution of the ion flux, and the step (c) adjusts the element in the second plasma processing apparatus by referring to the table created in the step (d) based on a difference between the reference distribution data and the distribution data.

According to one or more embodiments, the amount of change in the element includes an amount of change in a distribution of an electron density in the plasma.

According to one or more embodiments, the first substrate support has a first substrate supporting surface configured to support the substrate, the first substrate supporting surface has multiple first support regions, and the multiple first heaters are disposed in the respective multiple first support regions of the first substrate support.

According to one or more embodiments, the second substrate support has a second substrate supporting surface configured to support the substrate, the second substrate supporting surface has multiple second support regions, and the multiple second heaters are disposed in the respective multiple second support regions of the second substrate support.

According to one or more embodiments, there is provided a plasma processing apparatus including a chamber; a substrate support disposed in the chamber; and a controller, the controller configured to (a) acquire reference distribution data acquired in another plasma processing apparatus different from the plasma processing apparatus, the reference distribution data being data on a distribution of an ion flux that occurs between plasma generated in another chamber and a substrate placed at another substrate support in the another plasma processing apparatus, (b) acquire distribution data that is data on a distribution of an ion flux that occurs between plasma generated in the chamber and a substrate placed at the substrate support in the plasma processing apparatus, and (c) adjust an element capable of adjusting the ion flux in the plasma processing apparatus based on the distribution data acquired in the plasma processing apparatus and the reference distribution data acquired in the another plasma processing apparatus.

According to one or more embodiments of the present disclosure will be described below in detail with reference to the drawings. In the drawings, the same or similar elements have the same reference characters, and duplicated descriptions thereof will be omitted. Unless otherwise specified, the upward-downward positional relationship, the rightward/leftward positional relationship, and other positional relationship will be described based on the positional relationships shown in the drawings. The dimensional ratios in the drawings are not equal to actual ratios, and the actual ratios are not limited to the ratios shown in the drawings.

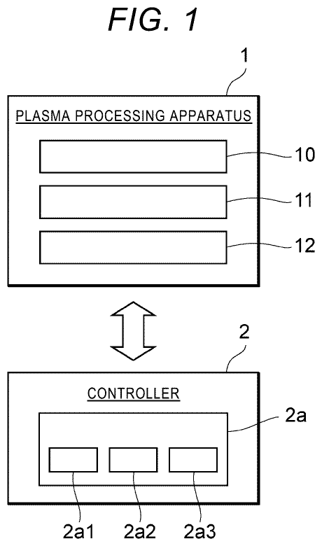

FIG. 1 illustrates an example of the configuration of a plasma processing system. In one or more embodiments of the present application, the plasma processing system includes a plasma processing apparatus 1 and a controller 2. The plasma processing system may include multiple plasma processing apparatuses 1 and multiple controllers 2. The plasma processing system is an example of a substrate processing system, and the plasma processing apparatus 1 is an example of a substrate processing apparatus. The plasma processing apparatus 1 includes a plasma processing chamber (also simply referred to as “chamber”) 10, a substrate support 11, and a plasma generator 12. The plasma processing chamber 10 has a plasma processing space. The plasma processing chamber 10 further has at least one gas supply port via which at least one processing gas is supplied into the plasma processing space, and at least one gas discharge port via which the gas is discharged from the plasma processing space. The gas supply port is connected to a gas supplier 20, which will be described later, and the gas discharge port is connected to an exhaust system 40, which will be described later. The substrate support 11 is disposed in the plasma processing space and has a substrate supporting surface that supports a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Furthermore, various types of plasma generators, including an alternating current (AC) plasma generator and a direct current (DC) plasma generator, may be used. According to one or more embodiments, an AC signal (AC power) used by an AC plasma generator has a frequency within a range from 100 kHz to 10 GHz. The AC signal therefore includes a radio frequency (RF) signal and a microwave signal. According to one or more embodiments, the RF signal has a frequency within a range from 100 kHz to 150 MHz.

The controller 2 processes computer-executable instructions that cause the plasma processing apparatus 1 to execute various steps described in the present disclosure. The controller 2 may be configured to control the elements of the plasma processing apparatus 1 to execute the various steps described herein below. According to one or more embodiments, the controller 2 may be partially or entirely included in the plasma processing apparatus 1. The controller 2 may control multiple plasma processing apparatuses 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid-state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

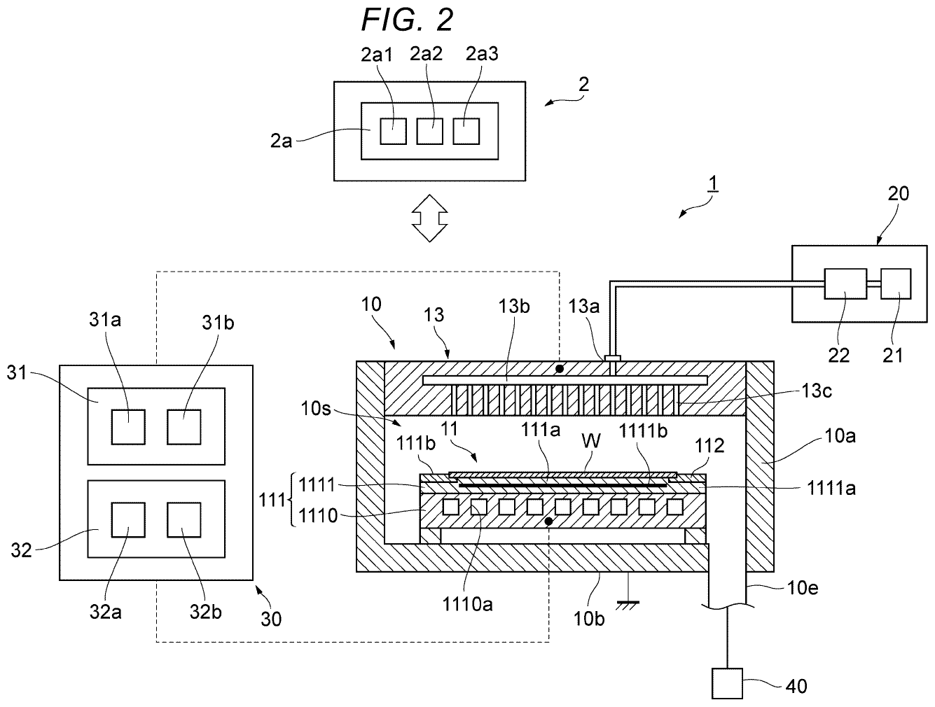

An example of the configuration of a capacitively coupled plasma processing apparatus will be described below as an example of the plasma processing apparatus 1. FIG. 2 illustrates an example of the configuration of the capacitively coupled plasma processing apparatus.

The capacitively coupled plasma processing apparatus 1 includes the plasma processing chamber 10, the gas supplier 20, a power source 30, and the exhaust system 40. The plasma processing apparatus 1 further includes the substrate support 11 and a gas introduction section. The gas introduction section is configured to introduce at least one processing gas into the plasma processing chamber 10. The gas introduction section includes a shower head 13. The substrate support 11 is disposed in the plasma processing chamber 10. The shower head 13 is disposed above the substrate support 11. According to one or more embodiments, the shower head 13 constitutes at least a portion of the ceiling of the plasma processing chamber 10. The plasma processing chamber 10 has a plasma processing space 10s defined by the shower head 13, a sidewall 10a and a bottom wall 10b of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body section 111 and a ring assembly 112. The body section 111 has a central region 111a, which supports a substrate W, and an annul ar region 111b, which supports the ring assembly 112. A wafer is an example of the substrate W. The annular region 111b of the body section 111 surrounds the central region 111a of the body section 111 in a plan view. The substrate W is placed on the central region 111a of the body section 111, and the ring assembly 112 is disposed on the annular region 111b of the body section 111 to surround the substrate W on the central region 111a of the body section 111. Therefore, the central region 111a is also called a substrate supporting surface that supports the substrate W, and the annular region 111b is also called a ring support surface that supports the ring assembly 112.

According to one or more embodiments, the body section 111 includes a base 1110 and an electrostatic chuck 1111. The base 1110 includes an electrically conductive member. The electrically conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. According to one or more embodiments, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Furthermore, at least one RF/DC electrode coupled to an RF power source 31 and/or a DC power source 32, which will be described later, may be disposed in the ceramic member 1111a. In this case, the at least one RF/DC electrode functions as the lower electrode. When a bias RF signal and/or DC signal, which will be described later, are supplied to the at least one RF/DC electrode, the RF/DC electrode is also called a bias electrode. Note that the electrically conductive member of the base 1110 and the at least one RF/DC electrode may function as multiple lower electrodes. The electrostatic electrode 1111b may instead function as the lower electrode. The substrate support 11 therefore includes at least one lower electrode.

The ring assembly 112 includes one or more annular members. According to one or more embodiments, the one or more annular members include one or more edge rings and at least one cover ring. The edge ring is made of an electrically conductive material or an insulating material, and the cover ring is made of an insulating material.

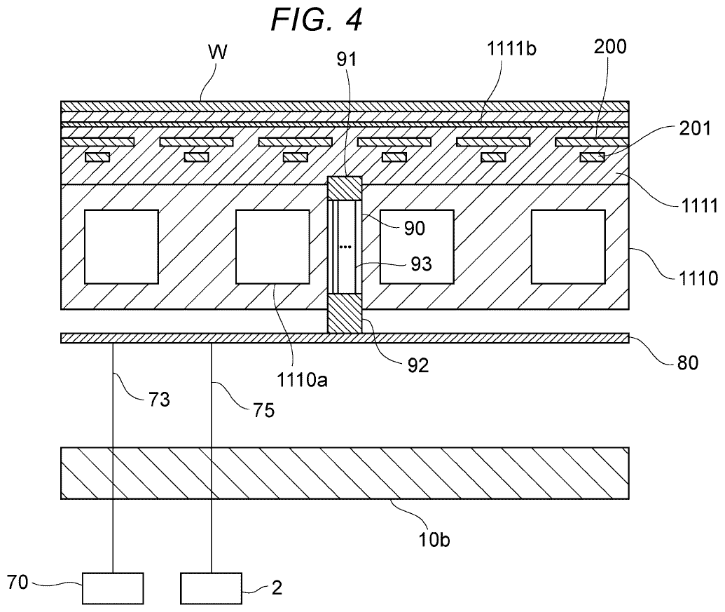

The substrate support 11 may further include a temperature controlling module configured to adjust the temperature of at least one of the electrostatic chuck 1111, the ring assembly 112, and the substrate to a target temperature. The temperature controlling module may include a heater, a heat transferring medium, a flow path 1110a, or a combination thereof. A heat transferring fluid, such as brine or gas, flows through the flow path 1110a. According to one or more embodiments, the flow path 1110a is formed in the base 1110, and one or more heaters are disposed in the ceramic member 1111a of the electrostatic chuck 1111. The substrate support 11 may further include a heat transferring gas supplier configured to supply a heat transferring gas to the gap between the rear surface of the substrate W and the central region 111a. The temperature controlling module will be described later in detail with reference to FIG. 4.

The shower head 13 is configured to introduce at least one processing gas from the gas supplier 20 into the plasma processing space 10s. The shower head 13 has at least one gas supply port 13a, at least one gas diffusion chamber 13b, and multiple gas introduction ports 13c. The processing gas supplied to the gas supply port 13a passes through the gas diffusion chamber 13b and is introduced into the plasma processing space 10s via the multiple gas introduction ports 13c. The shower head 13 further includes at least one upper electrode. The gas introduction section may include, in addition to the shower head 13, one or more side gas injectors (SGIs) attached to one or more openings formed in the sidewall 10a.

The gas supplier 20 may include at least one gas source 21 and at least one flow rate control device 22. According to one or more embodiments, the gas supplier 20 is configured to supply at least one processing gas from a corresponding gas source 21 to the shower head 13 via a corresponding flow rate control device 22. The flow rate control device 22 may include, for example, a mass flow controller or a pressure-controlled flow rate control device. The gas supplier 20 may further include at least one flow rate modulating device that modulates or pulses the flow rate of the at least one processing gas.

The power source 30 includes the RF power source 31 coupled to the plasma processing chamber 10 via at least one impedance matching circuit. The RF power source 31 is configured to supply at least one RF signal (RF power) to the at least one lower electrode and/or the at least one upper electrode. Plasma is thus formed from the at least one processing gas supplied into the plasma processing space 10s. The RF power source 31 can therefore function as at least a portion of the plasma generator 12. Furthermore, supplying the bias RF signal to the at least one lower electrode can generate a bias potential at the substrate W to attract the ionic component in the formed plasma to the substrate W.

According to one or more embodiments, the RF power source 31 includes a first RF generator 31a and a second RF generator 31b. The first RF generator 31a is coupled to the at least one lower electrode and/or the at least one upper electrode via the at least one impedance matching circuit, and configured to generate a source RF signal (source RF power) for plasma generation. According to one or more embodiments, the source RF signal has a frequency within a range from 10 MHz to 150 MHz. According to one or more embodiments, the first RF generator 31a may be configured to generate multiple source RF signals having different frequencies. The generated one or more source RF signals are supplied to the at least one lower electrode and/or the at least one upper electrode.

The second RF generator 31b is coupled to the at least one lower electrode via the at least one impedance matching circuit and configured to generate the bias RF signal (bias RF power). The frequency of the bias RF signal may be equal to or different from the frequency of the source RF signal. According to one or more embodiments, the bias RF signal has a frequency lower than the frequency of the source RF signal. According to one or more embodiments, the bias RF signal has a frequency within a range from 100 kHz to 60 MHz. According to one or more embodiments, the second RF generator 31b may be configured to generate multiple bias RF signals having different frequencies. The generated one or more bias RF signals are supplied to the at least one lower electrode. Furthermore, in various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. According to one or more embodiments, the first DC generator 32a is connected to the at least one lower electrode and configured to generate a first DC signal. The generated first DC signal is applied to the at least one lower electrode. According to one or more embodiments, the second DC generator 32b is connected to the at least one upper electrode and configured to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may each have a rectangular, trapezoidal, or triangular waveform or a combination thereof. According to one or more embodiments, a waveform generator that generates the sequence of voltage pulses from a DC signal is connected to and between the first DC generator 32a and the at least one lower electrode. The first DC generator 32a and the waveform generator therefore constitute a voltage pulse generator. When the second DC generator 32b and the waveform generator constitute the voltage pulse generator, the voltage pulse generator is connected to the at least one upper electrode. The voltage pulses may each have the positive or negative polarity. The sequence of the voltage pulses may further include one or more positive-polarity voltage pulses and one or more negative-polarity voltage pulses in one cycle. The first DC generator 32a and the second DC generator 32b may be provided in addition to the RF power source 31, or the first DC generator 32a may be provided in place of the second RF generator 31b.

The exhaust system 40 may be connected, for example, to a gas discharge port 10e disposed at a bottom portion of the plasma processing chamber 10. The exhaust system 40 may include a pressure adjusting valve and a vacuum pump. The pressure adjusting valve adjusts the pressure in the plasma processing space 10s. The vacuum pump may include a turbo molecular pump, a dry pump, or a combination thereof.

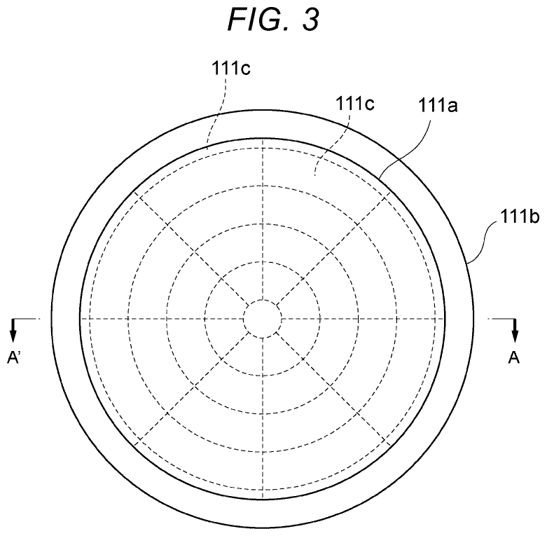

FIG. 3 shows an example of the upper surface of the substrate support 11. The substrate support 11 has the central region 111a, which supports the substrate W, and the annular region 111b, which supports the ring assembly 112, as shown in FIG. 3. The central region 111a has multiple zones 111c, as indicated by the broken lines in FIG. 3. In the present embodiment, the temperature controlling module can control the temperature of the substrate W or the substrate support 11 for each of the zones 111c. The number of the zones 111c and the area and shape of each of the zones 111c may be set as appropriate in accordance with conditions required to control the temperature of the substrate W.

FIG. 4 shows an example of a cross section of the substrate support 11. FIG. 4 shows a portion of the cross section of the substrate support 11 taken along the line AA′ in FIG. 3. The substrate support 11 includes the electrostatic chuck 1111, the base 1110, and a control substrate 80, as shown in FIG. 4. The electrostatic chuck 1111 has multiple heaters 200 and multiple resistors 201 disposed therein. In the present embodiment, one heater 200 and one resistor 201 are disposed in the electrostatic chuck 1111 in each of the zones 111c shown in FIG. 3. In each of the zones 111c, the resistor 201 is disposed near the heater 200. In one example, the resistor 201 may be disposed between the heater 200 and the base 1110 and closer to the heater 200 than to the base 1110. The resistors 201 are each so configured that the resistance thereof changes in accordance with the temperature. In one example, the resistors 201 may each be a thermistor (temperature sensor).

The base 1110 has one or more through holes 90, which pass through the base 1110 from the upper surface thereof (surface facing electrostatic chuck 1111) to the lower surface thereof (surface facing control substrate 80). The multiple heaters 200 and the multiple resistors 201 may be electrically connected to the control substrate 80 via the through hole 90. In the present embodiment, a connector 91 is fitted into the through hole 90 at one end thereof at the upper surface of the base 1110, and a connector 92 is fitted into the through hole 90 at one end thereof at the lower surface of the base 1110. The multiple heaters 200 and the multiple resistors 201 are electrically connected to the connector 91. The multiple heaters 200 and the multiple resistors 201 may be connected to the connector 91, for example, via wires disposed in the electrostatic chuck 1111. The connector 92 is electrically connected to the control substrate 80. In addition, multiple wires 93, which electrically connect the connector 91 and the connector 92 to each other, are disposed in the through hole 90. The multiple heaters 200 and the multiple resistors 201 can thus be electrically connected to the control substrate 80 via the through hole 90. Note that the connector 92 may function as a support member that fixes the control substrate 80 to the base 1110.

The control substrate 80 is a substrate at which elements that control the multiple heaters 200 and/or the multiple resistors 201 are disposed. The control substrate 80 can be disposed to face the lower surface of the base 1110 in parallel to the lower surface. The control substrate 80 may be disposed to be surrounded by an electrically conductive member. The control substrate 80 may be supported by the base 1110 via a support member other than the connector 92.

The control substrate 80 can be electrically connected to a power supplier 70 via wiring 73. That is, the power supplier 70 can be electrically connected to the multiple heaters 200 via the control substrate 80. The power supplier 70 generates power to be supplied to the multiple heaters 200. The power supplied from the power supplier 70 to the control substrate 80 can thus be supplied to the multiple heaters 200 via the connector 92, the wires 93, and the connector 91. Note that an RF filter that reduces RF may be disposed between the power supplier 70 and the control substrate 80. The RF filter may instead be provided outside the plasma processing chamber 10.

The control substrate 80 can be communicatively connected to the controller 2 via wiring 75. The wiring 75 may be an optical fiber. In this case, the control substrate 80 communicates with the controller 2 via optical communication. The wiring 75 may instead be metal wiring.

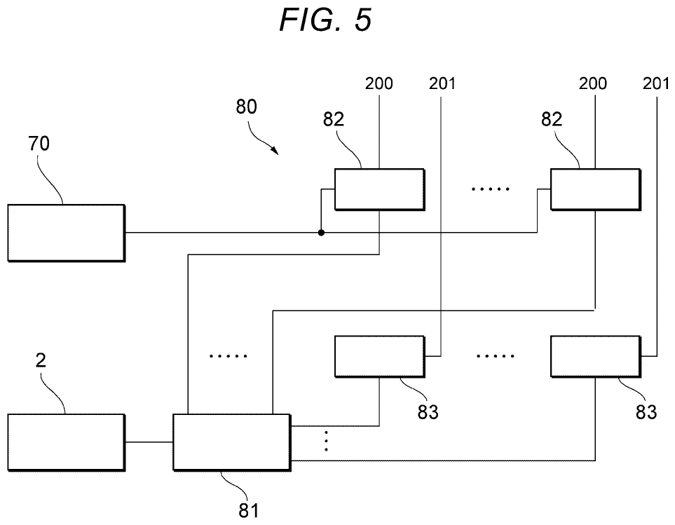

FIG. 5 is a block diagram showing an example of the configuration of the control substrate 80. A controller 81, and multiple suppliers 82 and multiple measuring sections 83, which are examples of the elements, are disposed at the control substrate 80. The multiple suppliers 82 and the multiple measuring sections 83 are provided in correspondence with the multiple heaters 200 and the multiple resistors 201, respectively. One supplier 82 and one measuring section 83 may be provided for one heater 200 and one resistor 201.

The measuring sections 83 each generate a voltage based on the resistance of the resistor 201 provided in correspondence with the measuring section 83, and supply the generated voltage to the controller 81. The measuring sections 83 may each be configured to convert the voltage generated in accordance with the resistance of the corresponding resistor 201 into a digital signal and output the digital signal to the controller 81.

The controller 81 controls the temperature of the substrate W in each of the zones 111c. The controller 81 controls the power supplied to the multiple heaters 200 based on a set temperature received from the controller 2 and the voltages indicated by the digital signals received from the measuring sections 83. As an example, the controller 81 calculates the temperatures of the resistors 201 (hereinafter also referred to as the “measured temperatures”) based on the voltages indicated by the digital signals received from the measuring sections 83. The controller 81 then controls the suppliers 82 based on the set temperature and the measured temperatures. The suppliers 82 each determine whether to supply the heater 200 with the power supplied from the power supplier 70 under the control of the controller 81. The suppliers 82 may each increase or decrease the power supplied from the power supplier 70 and supply the resultant power to the corresponding heater 200 under the control of the controller 81. The substrate W, the electrostatic chuck 1111, and/or the base 1110 can thus each be set at a predetermined temperature.

### Example of Plasma Processing Method

A plasma processing method performed in the plasma processing apparatus 1 includes an etching process of etching a film on the substrate W by using plasma. According to one or more embodiments, the present plasma processing method is performed by the controller 2.

First, the substrate W is loaded into the chamber 10 by a transport arm, placed on the substrate support 11 by a lifter, and suctioned and held by the substrate support 11 as shown in FIG. 2.

The processing gas is then supplied to the shower head 13 by the gas supplier 20, and is supplied from the shower head 13 to the plasma processing space 10s. The processing gas supplied at this point in time includes a gas that generates an active species required to etch the substrate W.

The one or more RF signals are supplied from the RF power source 31 to the upper electrode and/or the lower electrode. The atmosphere in the plasma processing space 10s may be exhausted via the gas discharge port 10e, and the interior of the plasma processing space 10s may be depressurized. As a result, plasma is generated in the plasma processing space 10s, and the substrate W is etched.

During the plasma processing, electric power is so supplied to each of the multiple heaters 200 that the temperature of each of the multiple heaters 200 (temperature detected by resistor 201) becomes the constant set temperature. The substrate W and the substrate support 11 are thus controlled to have the set temperature.

### Example of Method for Adjusting Plasma Processing Apparatus

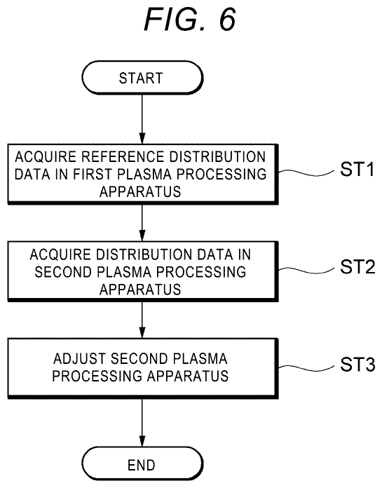

FIG. 6 is a flowchart showing an adjustment method according to one exemplary embodiment (hereinafter, also referred to as “present method”). The present method may include a method for correcting inter-apparatus differences that occur between multiple plasma processing apparatuses. According to one or more embodiments, a second plasma processing apparatus is adjusted with respect to a first plasma processing apparatus. The present method includes the steps of acquiring reference distribution data in the first plasma processing apparatus (ST1), acquiring distribution data in the second plasma processing apparatus (ST2), and adjusting the second plasma processing apparatus (ST3), as shown in FIG. 6. The process in each of the steps may be carried out by the plasma processing system shown in FIG. 1. The plasma processing apparatus 1 shown in FIG. 2 is an example of the first and second plasma processing apparatuses. In the following description, as an example, the controller 2 controls each section of the plasma processing apparatus 1 to perform the present method.

### Step ST1: Acquiring Reference Distribution Data in First Plasma Processing Apparatus

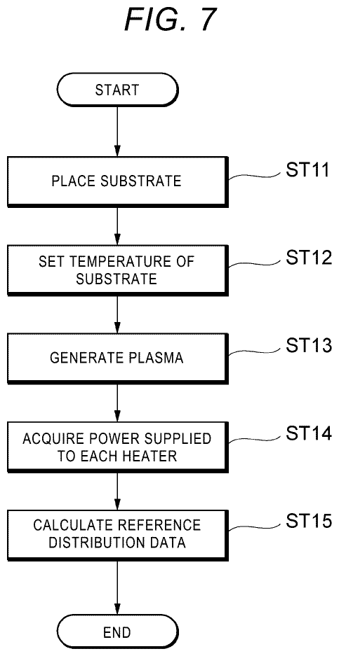

FIG. 7 is a flowchart showing an example of step ST1. In step ST1, the plasma processing is performed on the substrate to acquire the reference distribution data in the first plasma processing apparatus. The first plasma processing apparatus may be a plasma processing apparatus that serves as a reference apparatus for the adjustment. The first plasma processing apparatus may be determined in advance at the time of shipment, or may be determined by a user at a factory or a production line after shipment. The first plasma processing apparatus may be determined based on past processing records. The number of the first plasma processing apparatuses may be one or more. The substrate used to acquire the reference distribution data may be a dummy substrate by way of example. The dummy substrate may be a substrate at which no film has been formed. The dummy substrate may, for example, be a silicon wafer. The substrate may be a substrate in which semiconductor devices are formed. The plasma processing performed to acquire the reference distribution data may include plasma etching for forming the semiconductor devices in the substrate. That is, the substrate may include a predetermined film, and a mask film disposed on the predetermined film. The mask film may have a predetermined opening pattern.

Step ST1 includes the steps of placing the substrate (step ST11), setting the temperature of the substrate (step ST12), generating plasma (step ST13), acquiring the power supplied to each of the heaters (step ST14), and calculating the reference distribution data (step ST15), as shown in FIG. 7. In one example, step ST1 may be executed after installation, maintenance, or any other operation is performed on the first plasma processing apparatus.

First, in step ST11, the substrate is placed at the substrate support 11. Thereafter, in step ST12, the temperature of the substrate is set. In one example, the controller 2 controls the controller 81 disposed at the control substrate 80 in such a way that the temperature of the substrate becomes the set temperature in each of the zones 111c. The controller 2 acquires the power supplied to each of the heaters 200 in the state in which the temperature of the substrate is stable at the set temperature, and stores the acquired power in the storage 2a2. Note that the state in which the temperature of the substrate is stable at the set temperature may be the state after a predetermined period has elapsed since the substrate has been placed at the substrate support 11. The controller 2 may instead acquire the power supplied to each of the heaters 200 in a state in which no substrate is placed at the substrate support 11 but the temperature of the electrostatic chuck 1111 is stable at the set temperature, and stores the acquired power in the storage 2a2.

After the temperature of the substrate becomes stable at the set temperature, the plasma is generated in the plasma processing chamber 10 to perform the plasma processing on the substrate in step ST13. The plasma processing is performed based on a process recipe including multiple parameters. The process recipe may be the same as the process recipe used to perform the plasma processing (step ST23) in the second plasma processing apparatus, which will be described later. The parameters of the process recipe may include the type of the processing gas, the flow rate of the processing gas, the frequency, power, and duty ratio of the source RF signal, the frequency, power/voltage, and duty ratio of the bias signal, the pressure in the plasma processing chamber 10, and the distribution of a magnetic field applied to the interior of the plasma processing chamber 10.

Thereafter, in step ST14, the power supplied to each of the multiple heaters 200 is acquired. In steps ST13 and ST14, the controller 2 controls the power supplied to each of the heaters 200 in such a way that the temperature of the substrate becomes the set temperature in each of the zones 111c. The controller 2 then acquires the power supplied to each of the multiple heaters 200 in the state in which the plasma has been generated in step ST14. The controller 2 may store the power supplied to each of the multiple heaters 200 acquired in step ST14 in the storage 2a2.

Thereafter, in step ST15, the reference distribution data is calculated. The reference distribution data may be data on the distribution of the ion flux that occurs between the plasma generated in the plasma processing chamber 10 and the substrate.

Note that the ion flux distribution data may be calculated based on a heat flux that occurs between the substrate placed at the substrate support 11 and the plasma generated in the plasma processing chamber 10. For example, when the temperature of the substrate placed at the substrate support 11 is constant, an ion flux Γᵢ(m⁻²s⁻¹), which occurs between the substrate and the plasma generated in the plasma processing chamber 10, can be related to a heat flux Γₕₑₐₜ(W/m²), which occurs between the substrate and the plasma generated in the plasma processing chamber 10 as follows:

Γᵢ×Vdc∝Γₕₑₐₜ (1)

In Expression (1), Vdc (V) represents the bias voltage (V) that occurs between the dummy substrate and the plasma. The heat flux Γₕₑₐₜ, which occurs between the dummy substrate placed at the substrate support 11 and the plasma generated in the plasma processing chamber 10, may be calculated based on the supplied power acquired in step ST14. In one example, the heat flux Γₕₑₐₜ in each of the zones 111c may be calculated based on the expression below.

Γₕₑₐₜ=(P₀−Pₕₜᵣ)/A (2)

In Expression (2), P₀ represents the power (W) supplied to the heater 200 in the zone 111c in a state in which no plasma has been generated. That is, P₀ is the power acquired in the step ST12 and supplied to the heater 200 in the zone 111c. In Expression (2), Pₕₜᵣ represents the power (W) supplied to the heater 200 in the zone 111c in the state in which the plasma has been generated. That is, Pₕₜᵣ is the power acquired in the step ST14 and supplied to the heater 200 in the zone 111c. As an example, Pₕₜᵣ may be the power (W) supplied to the heater 200 in the zone 111c when the power (W) becomes substantially constant after the plasma is generated. In Expression (2), A represents the area (m²) of the zone 111c.

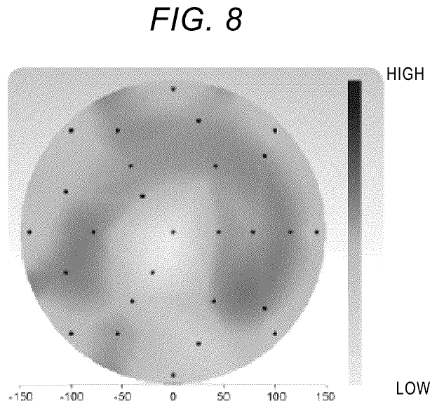

FIG. 8 shows an example of the reference distribution data. The reference distribution data can be acquired in the first plasma processing apparatus capable of normally performing the plasma processing. The reference distribution data may therefore be used as distribution data that serves as a reference for the ion flux that occurs between the plasma and the substrate. Note that multiple sets of reference distribution data may be acquired from multiple substrates, and one set of distribution data such as that as shown in FIG. 8 may be calculated based on the multiple sets of reference distribution data. Note that the reference distribution data includes not only the ion flux distribution itself shown in FIG. 8, but also various pieces of numerical information corresponding to the distribution. Note that FIG. 8 shows, as an example, distribution data calculated for a substrate having a diameter of 300 mm.

### Step ST2: Acquiring Distribution Data in Second Plasma Processing Apparatus

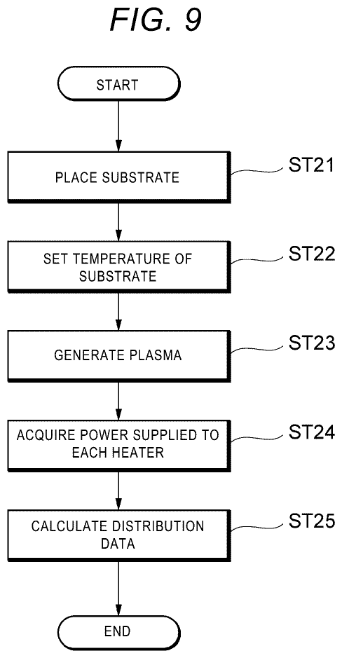

FIG. 9 is a flowchart showing an example of step ST2. In step ST2, the plasma processing is performed on a substrate to acquire the distribution data in the second plasma processing apparatus. The second plasma processing apparatus may be a plasma processing apparatus to be adjusted. The second plasma processing apparatus may be one located in the same factory or production line as the first plasma processing apparatus, or may be one that performs the plasma processing in accordance with the same process recipe as the first plasma processing apparatus. The number of the second plasma processing apparatuses may be one or more. The substrate used to acquire the distribution data may, for example, be the dummy substrate. The dummy substrate may be a substrate at which no film has been formed. The dummy substrate may, for example, be a silicon wafer. The plasma processing performed to acquire the distribution data may include plasma etching for forming semiconductor devices in the substrate. The plasma processing may be plasma processing performed in accordance with the same process recipe as the plasma processing performed in the first plasma processing apparatus described above. The substrate may be the same substrate used to acquire the reference distribution data in the first plasma processing apparatus described above, a substrate having the same structure thereof, or another substrate of the same type.

Step ST2 includes the steps of placing the substrate (step ST21), setting the temperature of the substrate (step ST22), generating the plasma (step ST23), acquiring the power supplied to each of the heaters (step ST24), and calculating the distribution data (step ST25), as shown in FIG. 9. In one example, step ST2 may be executed after installation, maintenance, or any other operation is performed on the second plasma processing apparatus.

First, in step ST21, the substrate is placed at the substrate support 11. Thereafter, in step ST22, the temperature of the substrate is set. In one example, the controller 2 controls the controller 81 disposed at the control substrate 80 in such a way that the temperature of the substrate becomes the set temperature in each of the zones 111c. The set temperature may be equal to the temperature set in step ST12 described above in the first plasma processing apparatus. The controller 2 acquires the power supplied to each of the heaters 200 in the state in which the temperature of the substrate is stable at the set temperature, and stores the acquired power in the storage 2a2. Note that the state in which the temperature of the substrate is stable at the set temperature may be the state after the predetermined period has elapsed since the substrate has been placed at the substrate support 11. The controller 2 may instead acquire the power supplied to each of the heaters 200 in the state in which no substrate is placed at the substrate support 11 but the temperature of the electrostatic chuck 1111 is stable at the set temperature, and stores the acquired power in the storage 2a2.

After the temperature of the substrate becomes stable at the set temperature, the plasma is generated in the plasma processing chamber 10 to perform the plasma processing on the substrate in step ST23.

Thereafter, in step ST24, the power supplied to each of the multiple heaters 200 is acquired. In steps ST23 and ST24, the controller 2 controls the power supplied to each of the heaters 200 in such a way that the temperature of the substrate becomes the set temperature in each of the zones 111c. The controller 2 then acquires the power supplied to each of the multiple heaters 200 in the state in which the plasma has been generated in step ST24. The controller 2 can store the power supplied to each of the multiple heaters 200 acquired in step ST24 in the storage 2a2.

Thereafter, in step ST25, the distribution data is calculated. The distribution data may be data on the distribution of the ion flux that occurs between the plasma generated in the plasma processing chamber 10 and the substrate. The ion flux distribution data may be calculated based on Expressions (1) and (2) described in step ST15.

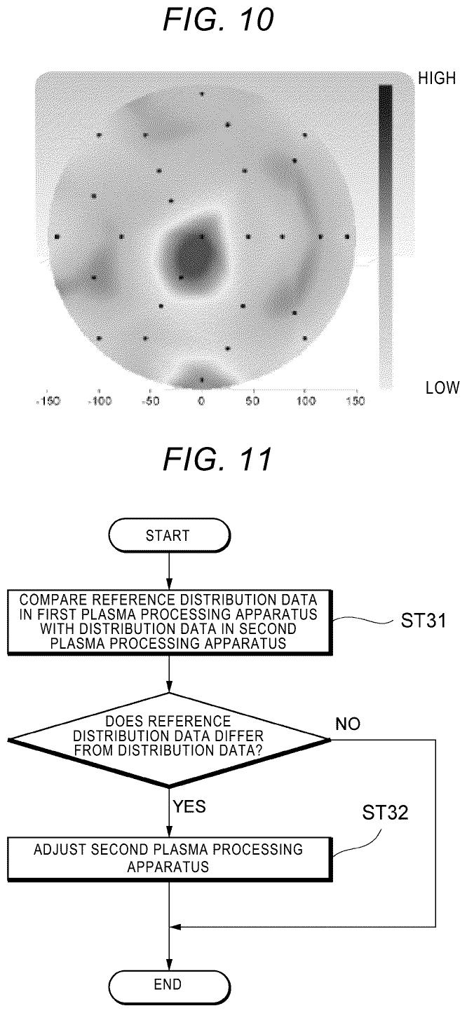

FIG. 10 shows an example of the distribution data (i.e., ion flux distribution data, as described in detail below). As an example, the distribution data shown in FIG. 10 is data acquired after installation, maintenance, or any other operation is performed on the second plasma processing apparatus. The distribution data in the second plasma processing apparatus is data acquired in the plasma processing using the same process recipe as the reference distribution data in the first plasma processing apparatus, and can be data that reflects a difference between the first and second plasma processing apparatuses. Note that FIG. 10 shows, as an example, distribution data calculated for a substrate having the diameter of 300 mm.

### Step ST3: Adjustment of Second Plasma Processing Apparatus

FIG. 11 is a flowchart showing an example of step ST3. In step ST3, an element capable of adjusting the distribution data in the second plasma processing apparatus is so adjusted that the distribution data acquired in the second plasma processing apparatus approaches the reference distribution data acquired in the first plasma processing apparatus.

Step ST3 includes the steps of comparing the distribution data in the second plasma processing apparatus with the reference distribution data in the first plasma processing apparatus (ST31), and adjusting an element capable of adjusting the distribution data in the second plasma processing apparatus (ST32), as shown in FIG. 11.

First, in step ST31, the distribution data in the second plasma processing apparatus is compared with the reference distribution data in the first plasma processing apparatus. When there is a difference greater than or equal to a predetermined value between the distribution data and the reference distribution data, step ST32 is executed, and when the difference is not greater than or equal to the predetermined value, step ST3 is terminated.

In the ion flux distribution shown in FIG. 10, the amount of ion flux increases in a central region and a lower region as compared with the amount of ion flux in the ion flux distribution shown in FIG. 8. In view of the fact described above, in step ST32, an element of the second plasma processing apparatus is so adjusted that the second plasma processing apparatus provides the same ion flux distribution as the first plasma processing apparatus. The element to be adjusted includes parameters relating to the plasma processing in the second plasma processing apparatus and parameters relating to the structure of the second plasma processing apparatus. The parameters relating to the plasma processing may include the type of the processing gas, the flow rate of the processing gas, the frequency, power, and duty ratio of the source RF signal, the frequency, power/voltage, and duty ratio of the bias signal, the pressure in the plasma processing chamber 10, and the distribution of a magnetic field applied to the interior of the plasma processing chamber 10. The element to be adjusted includes parameters relating to adjustment (calibration) of the output from the plasma processing apparatus. The adjustment (calibration) of the output from the plasma processing apparatus may include calibration of the power of the RF signal and the bias signal, calibration of a pressure sensor, calibration of the pressure adjusting valve, and calibration of the gas flow rate controlling device. Parameters relating to the structure (physical configuration) of the plasma processing apparatus may include the amount of tightening of screws used to attach each member of the apparatus to the body of the apparatus, the state of the gap between members of the apparatus (gap adjustment is made, for example, by using gap gauges and shims), and the state of electrical contact between members of the apparatus (state of contact via electrically conductive spirals).

According to the exemplary embodiment of the present disclosure, the adjustment method includes the steps of: (a) acquiring the reference distribution data, which is data on the distribution of the ion flux having occurred between the plasma generated in the chamber 10 and the substrate placed at the substrate support 11 in the first plasma processing apparatus; (b) acquiring the distribution data, which is data on the distribution of the ion flux having occurred between the plasma generated in the chamber 10 and the substrate placed at the substrate support 11 in the second plasma processing apparatus; and (c) adjusting an element capable of adjusting the ion flux in the second plasma processing apparatus based on the distribution data acquired in the second plasma processing apparatus and the reference distribution data acquired in the first plasma processing apparatus. According to the present exemplary embodiment, inter-apparatus differences between multiple plasma processing apparatuses can be corrected by using the distribution data relating to the distribution of the ion flux as an index, so that there is no need to change the parameters and other factors of the plasma processing apparatuses based on empirical rules. As a result, the time required to match the multiple plasma processing apparatuses with one another is shortened, and the accuracy of the matching is improved.

According to the exemplary embodiment of the present disclosure, variation in the ion flux distribution that occurs between multiple plasma processing apparatuses can be reduced. The inter-apparatus variation can thus be reduced in the plasma processing.

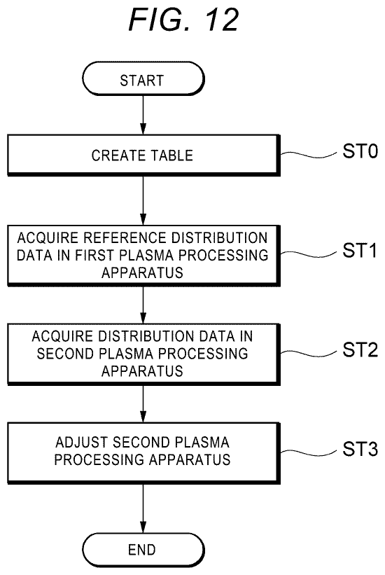

FIG. 12 is a flowchart showing the present method according to one exemplary embodiment. The present method may further include the step of creating a table (ST0), as shown in FIG. 12. That is, the present method includes the steps of creating a table (ST0), acquiring the reference distribution data in the first plasma processing apparatus (ST1), acquiring the distribution data in the second plasma processing apparatus (ST2), and adjusting the second plasma processing apparatus (ST3).

### Step ST1: Creating Table

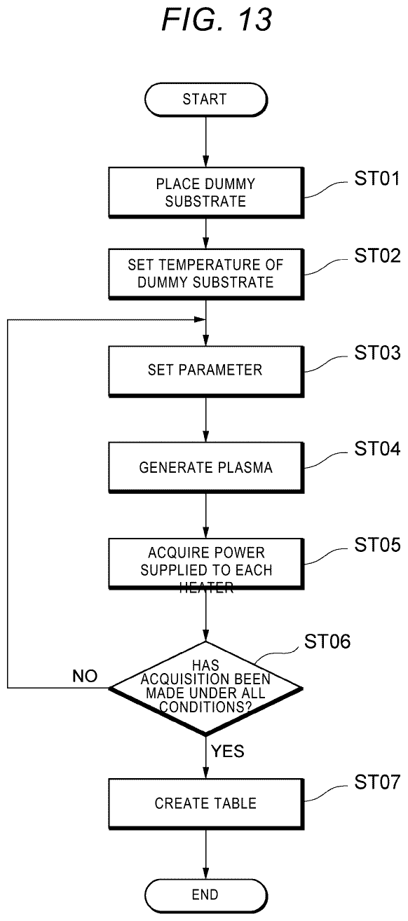

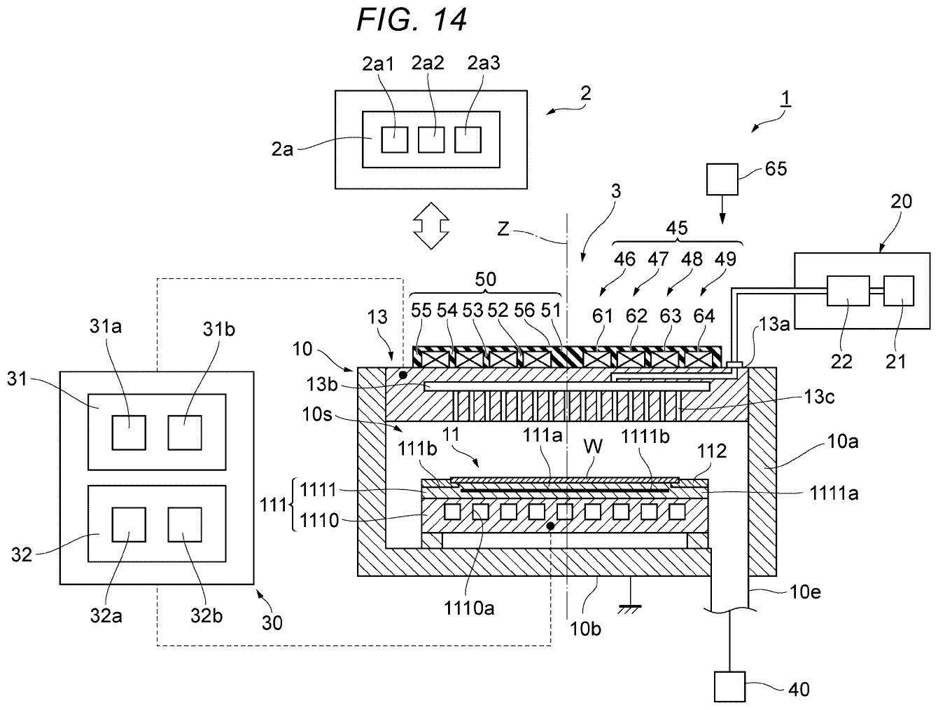

FIG. 13 is a flowchart showing an example of step ST0. The table created in step ST0 may be a table that stores the amount of change in an element capable of adjusting the ion flux distribution and the amount of change in the distribution of an ion flux that occurs due to the amount of change in the element with the two amounts associated with each other. The element capable of adjusting the ion flux distribution may include one or more parameters relating to the plasma generation. In one example, the parameter may be the magnetic flux density of a magnetic field applied to the interior of the plasma processing chamber 10, or any other parameter that can change the electron density distribution generated in the plasma processing chamber 10. As an example, the plasma processing apparatus 1 may have multiple electromagnets (see FIG. 14) configured to apply a magnetic field to the interior of the plasma processing chamber 10, in which case, the parameter may, for example, be a current and/or a voltage supplied to the multiple electromagnets.

Step ST0 includes the steps of placing the dummy substrate (ST01), setting the temperature of the dummy substrate (ST02), setting a parameter of the plasma processing (ST03), generating the plasma (ST04), acquiring the power supplied to each of the heaters (ST05), checking the acquisition of the supplied power (ST06), and creating the table (ST07), as shown in FIG. 13. In one example, step ST0 may be executed after installation, maintenance, or any other operation is performed on the plasma processing apparatus 1. Step ST0 may be executed in the first plasma processing apparatus, the second plasma processing apparatus, or another plasma processing apparatus.

First, in step ST01, the dummy substrate is placed at the substrate support 11. In one example, the dummy substrate may be a substrate at which no film has been formed. The dummy substrate may, for example, be a silicon wafer. Thereafter, in step ST02, the temperature of the dummy substrate is set. In one example, the controller 2 controls the controller 81 disposed at the control substrate 80 in such a way that the temperature of the dummy substrate becomes the set temperature in each of the zones 111c. The controller 2 acquires the power supplied to each of the heaters 200 in the state in which the temperature of the dummy substrate is stable at the set temperature, and stores the acquired power in the storage 2a2. Note that the state in which the temperature of the dummy substrate is stable at the set temperature may be the state after a predetermined period has elapsed since the dummy substrate has been placed at the substrate support 11.

The controller 2 may instead acquire the power supplied to each of the heaters 200 in the state in which no dummy substrate is placed at the substrate support 11 but the temperature of the electrostatic chuck 1111 is stable at the set temperature, and stores the acquired power in the storage 2a2.

After the temperature of the dummy substrate becomes stable at the set temperature, the parameter of the plasma processing performed on the dummy substrate is set in step ST03. The parameter may be the same as the parameter of the plasma processing performed on the substrate in each of steps ST1 and ST2. The plasma processing may include plasma etching for forming semiconductor devices in the dummy and process substrates.

The parameter of the plasma processing may include the type of the processing gas, the flow rate of the processing gas, the frequency, power, and duty ratio of the source RF signal, the frequency, power applied to the heaters, voltage applied to the electrodes (upper/lower), and duty ratio of the bias signal, the pressure in the plasma processing chamber 10, and the distribution of the magnetic field applied to the interior of the plasma processing chamber 10. Thereafter, in step ST04, the plasma is generated, and the plasma processing is performed on the dummy substrate.

Thereafter, in step ST05, the power supplied to each of the multiple heaters 200 is acquired. In steps ST04 and ST05, the controller 2 can control the power supplied to each of the heaters 200 in such a way that the temperature of the substrate in each of the zones 111c becomes the set temperature. The controller 2 then acquires the power supplied to each of the multiple heaters 200 in the state in which the plasma has been generated in the plasma processing chamber 10. The controller 2 may store the power supplied to each of the multiple heaters 200 acquired in step ST05 in the storage 2a2 in association with the one or more parameters of the plasma processing. In the present embodiment, the parameter may be a parameter capable of changing the distribution of the electron density distribution generated in the plasma processing chamber 10.

Thereafter, in step ST06, the controller 2 determines whether the power supplied to each of the multiple heaters 200 has been acquired under all conditions in which the parameter is changed. When the controller 2 determines that the supplied power has not been acquired under all the conditions (No in step ST06), the controller 2 returns to step ST03, and generates the plasma with the one or more parameters changed (step ST04). The parameter may be a parameter capable of changing the distribution of the electron density distribution generated in the plasma processing chamber 10. In one example, the parameter may be the magnetic flux density of the magnetic field applied to the interior of the plasma processing chamber 10. Thereafter, in a state in which the plasma has been generated based on the parameter newly set in step ST03, the power to be supplied to each of the multiple heaters 200 is newly acquired (step ST05). The controller 2 may store the power supplied to each of the multiple heaters 200 acquired in step ST05 in the storage 2a2 in association with the one or more parameters.

Thereafter, when the controller 2 determines that the power supplied to each of the multiple heaters 200 has been acquired under all conditions in which the parameter is changed (Yes in step ST06), the controller 2 stops the plasma processing. Thereafter, in step ST07, the controller 2 creates a table based on the value of the parameter and the power supplied to each of the multiple heaters 200 stored in the storage 2a2. The table may be a table that associates the amount of change in the parameter in the plasma processing performed in step ST04 with the amount of change in the distribution of the ion flux having occurred due to the amount of change in the parameter. Note that the ion flux distribution data may be calculated based on Expressions (1) and (2) described in step ST15.

In the table created in step ST07, the parameter stored in association with the amount of change in the ion flux may be the amount of change in the magnetic flux density of the magnetic field applied to the interior of the plasma, or the amount of change in the current and/or voltage supplied to the electromagnets, which generate the magnetic field. When the temperature of the substrate is constant, the ion flux Γᵢ, which occurs between the substrate and the plasma, can be related to the electron density in the plasma in accordance with the expression below.

Γᵢ∝nₑ×(Vdc)^{1/2} (3)

In Expression (3), ne represents the electron density (m⁻³) in the plasma. In Expression (3), Vdc represents the bias voltage (V) that occurs between the substrate and the plasma. The electron density in the plasma can be related to the magnetic flux density of the magnetic field applied to the interior of the plasma in accordance with the expression below.

nₑ∝H (4)

In Expression (4), H represents the magnetic flux density (G). The distribution of the magnetic flux density of the magnetic field applied to the interior of the plasma can thus be changed to change the distribution of the ion flux that occurs between the plasma and the substrate. As described above, in step ST07, the controller 2 can create, as an example, a table that associates the amount of change in the distribution of the magnetic flux density of the magnetic field applied to the interior of the plasma with the amount of change in the distribution of the ion flux.

In the table created in step ST07, the parameter stored in association with the amount of change in the ion flux may be a parameter capable of changing the distribution of the bias voltage that occurs between the substrate W placed at the substrate support 11 and the plasma generated in the plasma processing chamber 10. When the temperature of the substrate is constant, the ion flux Γᵢ, which occurs between the substrate and the plasma, can be related to the bias voltage (V), which occurs between the substrate and/or the ring assembly 112 and the plasma, in accordance with Expression (3) described above. The distribution of the bias voltage Vdc can therefore be changed to change the distribution of the ion flux that occurs between the plasma and the substrate. The controller 2 may thus create in step ST07, as an example, a table that associates the amount of change in the distribution of the bias voltage with the amount of change in the distribution of the ion flux. The controller 2 may further create in step ST07, as an example, a table that associates the amount of change in the voltage applied to the ring assembly 112 with the amount of change in the distribution of the ion flux. The controller 2 may still further create in step ST07, as an example, a table that associates the amount of change in the height of the ring assembly 112 with the amount of change in the distribution of the ion flux.

Steps ST1 and ST2 may be the same as those in the exemplary embodiment described above.

In step ST3, to adjust the second plasma processing apparatus, an element in the second plasma processing apparatus is adjusted by referring to the table created in step ST0 based on the difference between the reference distribution data and the distribution data.

In the example of the ion flux distribution shown in FIG. 10, the amount of ion flux increases in the central region and the lower region as compared with the amount of ion flux in the ion flux distribution shown in FIG. 8. In view of the fact described above, in step ST3, a correction value for an element capable of adjusting the distribution data in the second plasma processing apparatus is calculated based on the reference distribution data and the distribution data in such a way that the second plasma processing apparatus has the same ion flux distribution as the first plasma processing apparatus. The correction value for the element may be the difference between the reference distribution data and the distribution data. The correction value for the element may be calculated by the controller 2 of the second plasma processing apparatus, may be calculated by the controller 2 of the first plasma processing apparatus, or may be calculated by a server connected to the plasma processing apparatuses via a network and transmitted from the server to the controller 2 of the second plasma processing apparatus to be adjusted. The controller 2 then refers to the amount of change in the distribution of ion flux corresponding to the correction value in the table stored in the storage 2a2 in step ST0. The controller 2 then sets and adjusts a parameter used to correct the ion flux distribution based on the amount of change in the parameter corresponding to the amount of change in the ion flux distribution, which is contained in the table. In one example, the parameter may be the magnetic flux density of the magnetic field applied to the interior of the plasma, or the current and/or voltage supplied to the electromagnets, which generate the magnetic field.

In step ST3 described above, the correction value is calculated based on the reference distribution data and the distribution data, but the method for calculating the correction value is not limited to the method described above. In one example, data acquired in the plasma processing in each of steps ST1 and ST2 may be accumulated, and the parameter in the plasma processing may be corrected based on the accumulated data to correct the ion flux distribution. The data to be accumulated may include the parameter of the plasma processing, the power supplied to each of the heaters, the temperature of each of the heaters, the heat flux distribution, the ion flux distribution, and the type and structure of the substrate.

### Another Embodiment of Plasma Processing Apparatus 1

FIG. 14 illustrates another example of the configuration of the plasma processing apparatus. According to one or more embodiments, the plasma processing apparatus 1 may include an electromagnet assembly 3 including one or more electromagnets 45. The electromagnet assembly 3 is configured to generate a magnetic field in the chamber 10. According to one or more embodiments, the plasma processing apparatus 1 includes an electromagnet assembly 3 including multiple electromagnets 45. In the embodiment shown in FIG. 14, the multiple electromagnets 45 include electromagnets 46 to 49. The multiple electromagnets 45 are provided on or above the chamber 10. That is, the electromagnet assembly 3 is disposed on or above the chamber 10. In the example shown in FIG. 14, the multiple electromagnets 45 are provided on the shower head 13.

The one or more electromagnets 45 each include a coil. In the example shown in FIG. 14, the electromagnets 46 to 49 include coils 61 to 64. The coils 61 to 64 are wound around a center axis Z. The center axis Z may be an axis passing through the center of the substrate W or the substrate support 11. That is, in the electromagnet assembly 3, the coils 61 to 61 may each be a toroidal coil. The coils 61 to 64 are provided coaxially around the center axis Z at the same height position.

The electromagnet assembly 3 further includes a bobbin 50 (or yoke). The coils 61 to 64 are wound around the bobbin 50 (or yoke). The bobbin 50 is made, for example, of a magnetic material. The bobbin 50 has a columnar section 51, multiple cylindrical sections 52 to 55, and a base section 56. The base section 56 has a substantially disk-like shape, and the center axis thereof coincides with the center axis Z. The columnar section 51 and the multiple cylindrical sections 52 to 55 extend downward from the lower surface of the base section 56. The columnar section 51 has a substantially circular columnar shape, and the center axis thereof substantially coincides with the center axis Z. The radius of the columnar section 51 is, for example, 30 mm. The cylindrical sections 52 to 55 extend around the center axis Z outside the columnar section 51.

The coil 61 is wound along the outer circumferential surface of the columnar section 51 and housed in a groove between the columnar section 51 and the cylindrical section 52. The coil 62 is wound along the outer circumferential surface of the cylindrical section 52 and housed in a groove between the cylindrical section 52 and the cylindrical section 53. The coil 63 is wound along the outer circumferential surface of the cylindrical section 53 and housed in a groove between the cylindrical section 53 and the cylindrical section 54. The coil 64 is wound along the outer circumferential surface of the cylindrical section 54 and housed in a groove between the cylindrical section 54 and the cylindrical section 55.

A current source 65 is connected to each of the coils contained in the one or more electromagnets 45. The controller 2 controls the current source 65 to start and stop supplying the current to each of the coils contained in the one or more electromagnets 45, and further controls the direction of the current and the value of the current. Note that when the plasma processing apparatus 1 includes the multiple electromagnets 45, the coils of the multiple electromagnets 45 may be connected to a single current source, or may be separately connected to different current sources.

The one or more electromagnets 45 form a magnetic field axially symmetrical with respect to the center axis Z in the chamber 10. Controlling the current supplied to each of the one or more electromagnets 45 allows adjustment of the magnetic field intensity distribution (or magnetic flux density) in the radial direction from the center axis Z. The plasma processing apparatus 1 can thus adjust the radial distribution of the density of the plasma generated in the chamber 10. Other configurations, operations, and/or functions of the plasma processing apparatus 1 shown in FIG. 14 may be the same as those of the plasma processing apparatus 1 described in the example shown in FIG. 2.

The embodiments of the present disclosure further include the following aspects.

### (Appendix 1)

An adjustment method including the steps of:
(a) acquiring reference distribution data that is data on a distribution of an ion flux that occurs between plasma generated in a first chamber and a substrate placed at a first substrate support disposed in the first chamber in a first plasma processing apparatus including the first chamber and the first substrate support;
(b) acquiring distribution data that is data on a distribution of an ion flux that occurs between plasma generated in a second chamber and a substrate placed at a second substrate support disposed in the second chamber in a second plasma processing apparatus including the second chamber and the second substrate support; and
(c) adjusting an element capable of adjusting the ion flux in the second plasma processing apparatus based on the distribution data acquired in the second plasma processing apparatus and the reference distribution data acquired in the first plasma processing apparatus.

### (Appendix 2)

The adjustment method according to Appendix 1, wherein
the step (a) includes the steps of
(a-1) placing the substrate at the first substrate support,
(a-2) generating the plasma in the first chamber to perform plasma processing on the substrate,
(a-3) supplying power to each of multiple first heaters disposed in the first substrate support,
(a-4) acquiring the power supplied to each of the multiple first heaters in the state in which the plasma is generated in the first chamber, and
(a-5) calculating the reference distribution data based on the power acquired for each of the multiple first heaters in the step (a-4).

### (Appendix 3)

The adjustment method according to Appendix 1 or 2, wherein
the step (b) includes the steps of
(b-1) placing the substrate at the second substrate support,
(b-2) generating the plasma in the second chamber to perform plasma processing on the substrate,
(b-3) supplying power to each of multiple second heaters disposed in the second substrate support,
(b-4) acquiring the power supplied to each of the multiple second heaters in the state in which the plasma is generated in the second chamber, and
(b-5) calculating the distribution data based on the power acquired for each of the multiple second heaters in the step (b-4).

### (Appendix 4)

The adjustment method according to any one of Appendices 1 to 3, wherein
the element in the step (c) includes at least one of a parameter relating to plasma processing in the second plasma processing apparatus and a parameter relating to a structure of the second plasma processing apparatus.

### (Appendix 5)

The adjustment method according to any one of Appendices 1 to 4, further including the step of
(d) creating a table that associates an amount of change in the distribution of the ion flux with an amount of change in the element capable of adjusting the distribution of the ion flux,
wherein the step (c) adjusts the element in the second plasma processing apparatus by referring to the table created in the step (d) based on a difference between the reference distribution data and the distribution data.

### (Appendix 6)

The adjustment method according to Appendix 5, wherein the amount of change in the element includes an amount of change in a distribution of an electron density in the plasma.

### (Appendix 7)

The adjustment method according to Appendix 2, wherein
the first substrate support has a first substrate supporting surface configured to support the substrate,
the first substrate supporting surface has multiple first support regions, and
the multiple first heaters are disposed in the respective multiple first support regions of the first substrate support.

### (Appendix 8)

The adjustment method according to Appendix 3, wherein
the second substrate support has a second substrate supporting surface configured to support the substrate,
the second substrate supporting surface has multiple second support regions, and
the multiple second heaters are disposed in the respective multiple second support regions of the second substrate support.

### (Appendix 9)

A plasma processing apparatus including a chamber; a substrate support disposed in the chamber; and a controller, wherein
the controller is configured to
(a) acquire reference distribution data acquired in another plasma processing apparatus different from the plasma processing apparatus, the reference distribution data being data on a distribution of an ion flux that occurs between plasma generated in another chamber and a substrate placed at another substrate support in the another plasma processing apparatus,
(b) acquire distribution data that is data on a distribution of an ion flux that occurs between plasma generated in the chamber and a substrate placed at the substrate support in the plasma processing apparatus, and
(c) adjust an element capable of adjusting the ion flux in the plasma processing apparatus based on the distribution data acquired in the plasma processing apparatus and the reference distribution data acquired in the another plasma processing apparatus.

The aforementioned embodiments have been described for illustration, and are not intended to limit the scope of the present disclosure. Various modifications may be made to the aforementioned embodiments without departing from the scope and gist of the present disclosure. For example, some elements in an embodiment may be added to another embodiment. Some elements in an embodiment may be replaced with corresponding elements in another embodiment.

1. An adjustment method including the steps of:
(a) acquiring reference distribution data that is data on a distribution of an ion flux that occurs between plasma generated in a first chamber and a first substrate placed at a first substrate support disposed in the first chamber, a first plasma processing apparatus including the first chamber and the first substrate support;
(b) acquiring distribution data, the distribution data including a distribution of an ion flux that occurs between plasma generated in a second chamber and a second substrate placed at a second substrate support disposed in the second chamber, a second plasma processing apparatus including the second chamber and the second substrate support; and
(c) changing an element capable of adjusting the ion flux in the second plasma processing apparatus based on the distribution data acquired in the second plasma processing apparatus and the reference distribution data acquired in the first plasma processing apparatus.

2. The adjustment method according to claim 1, wherein
the step (a) includes the steps of
(a-1) placing the first substrate at the first substrate support,
(a-2) generating the plasma in the first chamber to perform plasma processing on the first substrate,
(a-3) supplying power to each of multiple first heaters disposed in the first substrate support,
(a-4) acquiring the power supplied to each of the multiple first heaters in the state in which the plasma is generated in the first chamber, and
(a-5) calculating the reference distribution data based on the power acquired for each of the multiple first heaters in the step (a-4).

3. The adjustment method according to claim 1, wherein
the step (b) includes the steps of
(b-1) placing the second substrate at the second substrate support,
(b-2) generating the plasma in the second chamber to perform plasma processing on the second substrate,
(b-3) supplying power to each of multiple second heaters disposed in the second substrate support,
(b-4) acquiring the power supplied to each of the multiple second heaters in the state in which the plasma is generated in the second chamber, and
(b-5) calculating the distribution data based on the power acquired for each of the multiple second heaters in the step (b-4).

4. The adjustment method according to claim 1, wherein
the element in the step (c) includes at least one of a parameter relating to plasma processing in the second plasma processing apparatus and a parameter relating to a structure of the second plasma processing apparatus.

5. The adjustment method according to claim 1, further including the step of:
(d) creating a table that associates an amount of change in the distribution of the ion flux in the second plasma processing apparatus with an amount of change in the element capable of adjusting the distribution of the ion flux in the second plasma processing apparatus,
wherein the step (c) adjusts the element in the second plasma processing apparatus by referring to the table created in the step (d) based on a difference between the reference distribution data and the distribution data.

6. The adjustment method according to claim 5, wherein the amount of change in the element includes an amount of change in a distribution of an electron density in the plasma generated in the second chamber.

7. The adjustment method according to claim 2, wherein
the first substrate support has a first substrate supporting surface configured to support the substrate,
the first substrate supporting surface has multiple first support regions, and
each of the multiple first heaters are disposed in a respective one of the multiple first support regions of the first substrate support.

8. The adjustment method according to claim 3, wherein
the second substrate support has a second substrate supporting surface configured to support the substrate,
the second substrate supporting surface has multiple second support regions, and
each of the multiple second heaters are disposed in a respective one of the multiple second support regions of the second substrate supporting surface.

9. A plasma processing apparatus comprising:
a chamber;
a substrate support disposed in the chamber; and
a controller configured to:
(a) acquire reference distribution data acquired in a second plasma processing apparatus different from the plasma processing apparatus, the reference distribution data being data on a distribution of an ion flux that occurs between plasma generated in a second chamber and a substrate placed at a second substrate support in the second plasma processing apparatus,
(b) acquire distribution data that is data on a distribution of an ion flux that occurs between plasma generated in the chamber and a substrate placed at the substrate support in the plasma processing apparatus, and
(c) changing an element capable of adjusting the ion flux in the plasma processing apparatus based on the distribution data acquired in the plasma processing apparatus and the reference distribution data acquired in the second plasma processing apparatus.

10. The plasma processing apparatus according to claim 9, wherein the substrate support includes:
an electrostatic chuck including:
multiple heaters; and
multiple resistors;
a base; and
a control substrate electrically connected to the multiple heaters and to the multiple resistors.

11. The plasma processing apparatus according to claim 10, further comprising a power supplier electrically connected to the multiple heaters via the control substrate,
wherein the base includes a though hole including:
a first connector disposed at an upper surface of the base; and
a second connector disposed at a lower surface of the base, and
the second connector fixes the control substrate to the base and electrically connects the control substrate to the multiple heaters and to the multiple resistors.

12. The plasma processing apparatus according to claim 11, further comprising a plurality of wires electrically connecting the first connector and the second connector.

13. The plasma processing apparatus according to claim 10, wherein
the step (a) includes the steps of
(a-1) placing the substrate at the substrate support,
(a-2) generating the plasma in the chamber to perform plasma processing on the substrate,
(a-3) supplying power to each of multiple first heaters disposed in the substrate support,
(a-4) acquiring the power supplied to each of the multiple heaters in the state in which the plasma is generated in the chamber, and
(a-5) calculating the reference distribution data based on the power acquired for each of the multiple heaters in the step (a-4).

14. The plasma processing apparatus according to claim 10, wherein
the element in the step (c) includes at least one of a parameter relating to plasma processing in the plasma processing apparatus and a parameter relating to a structure of the plasma processing apparatus.

15. The plasma processing apparatus according to claim 14, wherein the parameter relating to the plasma processing includes at least one of a type of a processing gas, a flow rate of the processing gas, a frequency, a power and duty ratio of a source RF signal, a frequency, power and duty ratio of the bias signal, a pressure in the chamber, and a distribution of a magnetic field applied to an interior of the chamber.

16. The plasma processing apparatus according to claim 14, wherein the parameter relating to the structure of the plasma processing apparatus includes an amount of tightening of screws used to attach each member of the plasma processing apparatus, a state of a gap between the members of the plasma processing apparatus and a state of electrical contact between the members of the plasma processing apparatus.

17. The plasma processing apparatus according to claim 9, wherein the controller is further configured to (d) create a table that associates an amount of change in the distribution of the ion flux in the plasma processing apparatus with an amount of change in the element capable of adjusting the distribution of the ion flux in the plasma processing apparatus, and
the step (c) including adjusting the element in the plasma processing apparatus by referring to the table created in the step (d) based on a difference between the reference distribution data and the distribution data.

18. The plasma processing apparatus according to claim 17, wherein the amount of change in the element includes an amount of change in a distribution of an electron density in the plasma generated in the chamber.

19. The plasma processing apparatus according to claim 10, wherein
the substrate support has a first substrate supporting surface configured to support the substrate,
the first substrate supporting surface has multiple first support regions, and
each of the multiple heaters are disposed in a respective one of the multiple first support regions of the first substrate supporting surface.

20. The plasma processing apparatus according to claim 19, further comprising a power supplier electrically connected to the multiple heaters via the control substrate,
wherein the base includes a though hole having:
a first connector disposed at an upper surface of the base; and
a second connector disposed at a lower surface of the base, and
the second connector fixes the control substrate to the base and electrically connects the control substrate to the multiple heaters and to the multiple resistors.
